(19) United States
(12) Patent Application Publication
(10) Pub. No.: US 2024/0327761 A1
(43) Pub. Date: Oct. 3, 2024

(54) CLEANING COMPOSITIONS AND METHODS OF USE THEREOF

(71) Applicant: Fujifilm Electronic Materials U.S.A. , Inc., N. Kingstown, RI (US)

(72) Inventors: Wei Li, Queen Creek, AZ (US); Bin Hu, Chandler, AZ (US); Nobuaki Sugimura, Gilbert, AZ (US)

(21) Appl. No.: 18/616,337

(22) Filed: Mar. 26, 2024

Related U.S. Application Data
(60) Provisional application No. 63/493,533, filed on Mar. 31, 2023.

(51) Int. Cl. C11D 7/36; C11D 7/26; C11D 7/32; C11D 7/34; C11D 7/50; H01L 21/02

(52) U.S. Cl. CPC C11D 7/36; C11D 7/263; C11D 7/265; C11D 7/3209; C11D 7/3245; C11D 7/34; C11D 7/50; H01L 21/02057

(57) ABSTRACT

The present disclosure relates to cleaning compositions that can be used to clean semiconductor substrates. These cleaning compositions can be used to remove defects arising from previous processing steps on these semiconductor substrates. These cleaning compositions can remove the defects/contaminants from the semiconductor substrates and thereby make the substrates appropriate for further processing. The cleaning compositions described herein primarily contain at least one organic acid and at least one organosilane compound.

### CROSS-REFERENCE TO RELATED APPLICATION

The present application claims priority to U.S. Provisional Application Ser. No. 63/493,533, filed on Mar. 31, 2023, the contents of which are hereby incorporated by reference in their entirety.

### BACKGROUND

The semiconductor industry is continually driven to improve chip performance by further miniaturization of devices through process and integration innovations. Chemical Mechanical Polishing/Planarization (CMP) is a powerful technology as it makes many complex integration schemes at the transistor level possible, thereby facilitating increased chip density.

CMP is a process used to planarize/flatten a wafer surface by removing material using abrasion-based physical processes concurrently with surface-based chemical reactions. In general, a CMP process involves applying a CMP slurry (e.g., an aqueous chemical formulation) to a wafer surface while contacting the wafer surface with a polishing pad and moving the polishing pad in relation to the wafer. Slurries typically include an abrasive component and dissolved chemical components, which can vary significantly depending upon the materials (e.g., metals, metal oxides, metal nitrides, dielectric materials such as silicon oxide and silicon nitride, etc.) present on the wafer that will be interacting with the slurry and the polishing pad during the CMP process.

After CMP processing, a variety of contaminants may be present on the surface of the polished wafer. Contaminants may include, for example, particulate abrasives from the CMP slurry, organic residues from the pad or slurry components, and materials removed from the wafer during the CMP process. If left on the surface of the polished wafer, these contaminants may lead to failures during further wafer processing steps and/or to diminished device performance. FIG. 1 shows four different defect mode types after CMP polish-scratches, residual abrasives, organic particles in a blob, and organic particles in dust.

Thus, the contaminants need to be effectively removed so that the wafer may predictably undergo further processing and/or to achieve optimal device performance. The process of removing these post-polishing contaminants or residues on the wafer surface after CMP is called post-CMP cleaning. The formulations used in this post-CMP cleaning process are called post-CMP (P-CMP) cleaning solutions or compositions. These P-CMP cleaning solutions/compositions are intended to solubilize defects remaining on the wafer surface after the CMP step and thereby remove these defects and make the wafer surface clean for further processing.

The post-CMP cleaning process can be carried out in brush boxes (containing brushes for mechanical action) or Megasonics (advanced ultrasonic/sonication for mechanical action) that come as attachments/modules on the CMP polishing tools. To begin a P-CMP cleaning process, the brush box or the Megasonic is flooded with a P-CMP cleaning composition. Thereafter, after the CMP polishing process has been completed, the CMP polished wafers are passed through the brush box and/or Megasonic in the CMP polishing tool that contains the P-CMP cleaning composition. In a best case scenario, the wafers come out dry and cleaned with very low defectivity after being subjected to chemical action by the post-CMP cleaning composition and scrubbing mechanical action by the brush and/or the sonication.

### SUMMARY

In semiconductor chip manufacturing, defectivity on the wafer surface is key to the yield of the wafers. A typical wafer goes through about 1000 processes before chips are made and the individual dies are cut from the wafer. At each of these processes, the defectivity is monitored pre-& post-process. CMP is an important step in chip manufacturing. However, the CMP step introduces lots of defects after the polishing steps (see FIG. 1). Thus, after the CMP polishing step, a post-CMP (P-CMP) cleaning composition is typically applied to the wafer surface to reduce the defects.

The present disclosure features novel P-CMP cleaning compositions which not only reduce wafer defects but also provide various other favorable electrochemical attributes that are critical for chip manufacturing. For example, these P-CMP cleaning compositions not only reduce defectivity (thereby increasing yield), but also minimize galvanic corrosion (or other forms of corrosion) when metals and metal oxides and nitrides come in contact with each other on a patterned wafer.

The present disclosure relates to cleaning compositions that can be used to clean semiconductor substrates (e.g., wafers). For example, these cleaning compositions can be used to remove defects arising from previous processing steps, such as CMP, on these semiconductor substrates. In particular, these cleaning compositions can remove the defects/contaminants from the semiconductor substrates and thereby make the substrates appropriate for further processing. The cleaning compositions described herein generally contain an organic acid and at least one organosilane compound, and have a pH in the 1 to 14 range.

In one aspect, the present disclosure features a cleaning composition that includes at least one first organic acid, at least one organosilane compound, and water, in which the cleaning composition is substantially free of an abrasive.

In another aspect, the present disclosure features a method for cleaning a substrate surface, the method including contacting a substrate having a surface containing SiN, SiC, TiN, W, Ru, Mo, TEOS, Cu, TaN, Co, silicon oxycarbide, or p-Si with the cleaning composition described herein.

In another aspect, the present disclosure features a method for cleaning a substrate, the method including contacting a substrate with the cleaning composition described herein.

This summary is provided to introduce a selection of concepts that are further described below in the detailed description. This summary is not intended to identify key or essential features of the claimed subject matter, nor is it intended to be used as an aid in limiting the scope of the claimed subject matter.

### DESCRIPTION OF DRAWINGS

FIG. 1: Examples of various types of defectivity encountered before and after post-CMP cleaning with post-CMP cleaners. The four defectivity modes shown (scratch, residual abrasive, and organic particles (blob and dust)) primarily contribute to the overall total defect counts (TDC) seen on the wafers. The defect images were collected on an Applied Materials SEMVision G5 SEM tool.

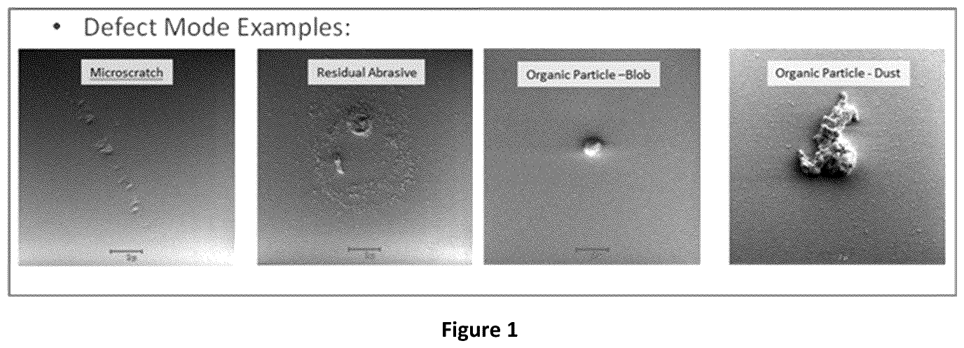

### DETAILED DESCRIPTION

Embodiments disclosed herein relate generally to cleaning compositions and methods of using such compositions to clean substrates (e.g., semiconductor substrates such as wafers). In particular, the cleaning compositions can be used to clean substrates after a CMP process. However, the cleaning compositions described herein can also find use in removing residue and/or contaminants from a substrate surface after an etching process, after an ashing process, or after a plating process.

As defined herein, residue and/or contaminants can include components present in a CMP polishing composition that has been used to polish the substrate to be cleaned (e.g., abrasives, molecular components, polymers, acids, bases, salts, surfactants, etc.), compounds produced during the CMP process as a result of chemical reactions between the substrate and the polishing composition and/or between components of the polishing composition, polishing pad polymeric particles, polishing byproducts, organic or inorganic residues (from CMP slurry or CMP pad), substrate (or wafer) particles liberated during the CMP process, and/or any other removable materials that are known to deposit on a substrate after a CMP process.

In one or more embodiments, a cleaning composition described herein includes (1) at least one first organic acid, (2) at least one organosilane compound, and (3) a solvent (e.g., water). In one or more embodiments, a cleaning composition of the present disclosure can include from about 0.00001% to about 50% (e.g., from about 0.01% to about 5%) by weight of the at least one first organic acid, from about 0.0001% to about 20% (e.g., from about 0.001% to about 10%) by weight of the at least one organosilane compound, and the remaining percent by weight (e.g., from about 60% to about 99.99% by weight) of solvent (e.g., deionized water).

In one or more embodiments, the present disclosure provides for a concentrated P-CMP cleaning composition that can be diluted with water to obtain a point-of-use (POU) cleaning composition by up to a factor of 20, or up to a factor of 50, or up to a factor of 100, or up to a factor of 200, or up to a factor of 400, or up to a factor of 800, or up to a factor of 1000. In other embodiments, the present disclosure provides a point-of-use (POU) cleaning composition that can be used directly for cleaning substrate surfaces without dilution.

In one or more embodiments, a POU cleaning composition can include from about 0.00001% to about 5% by weight of at least one first organic acid (e.g., a polycarboxylic acid), and from about 0.0001% to about 5% by weight of at least one organosilane compound. In another embodiment, a POU cleaning composition can include from about 0.00001% to about 5% by weight of at least one first organic acid (e.g., a polycarboxylic acid), from about 0.00001% to about 5% by weight of at least one corrosion inhibitor (e.g., an amino acid) different from the first organic acids, and from about 0.001% to about 5% by weight of at least one organosilane compound.

In one or more embodiments, a concentrated P-CMP cleaning composition can include from about 0.01% to about 50% by weight of at least one first organic acid (e.g., a polycarboxylic acid), and from about 0.005% to about 20% by weight of at least one organosilane compound. In another embodiment, a concentrated P-CMP cleaning composition can include from about 0.01% to about 30% by weight of at least one first organic acid (e.g., a polycarboxylic acid), from about 0.01% to about 20% by weight of at least one corrosion inhibitor (e.g., an amino acid) different from the first organic acid, and from about 0.005% to about 15% by weight of at least one organosilane compound.

In one or more embodiments, the cleaning composition described herein can include at least one (e.g., two, three, or four) organic acid. As used herein, the term “acid” includes an acid or a salt thereof (e.g., a potassium or sodium salt thereof). In some embodiments, the at least one organic acid can be selected from the group consisting of carboxylic acids (e.g., monocarboxylic acids, polycarboxylic acids, and dienoic acids), amino acids, sulfonic acids, phosphoric acid, acrylic acids, and phosphonic acids, or salts thereof. In some embodiments, the at least one organic acid can be an acid or a salt thereof selected from the group consisting of formic acid, gluconic acid, acetic acid, malonic acid, citric acid, propionic acid, malic acid, adipic acid, succinic acid, lactic acid, oxalic acid, hydroxyethylidene diphosphonic acid, 2-phosphono-1,2,4-butane tricarboxylic acid, aminotrimethylene phosphonic acid, hexamethylenediamine tetra(methylenephosphonic acid), bis(hexamethylene)triamine phosphonic acid, amino acetic acid, peracetic acid, potassium acetate, phenoxyacetic acid, glycine, bicine, diglycolic acid, glyceric acid, tricine, alanine, histidine, valine, phenylalanine, proline, glutamine, aspartic acid, ascorbic acid, glutamic acid, arginine, lysine, tyrosine, benzoic acid, ethylenediaminetetraacetic acid (EDTA), diethylenetriaminepentaacetic acid, (DTPA), 2,4-pentadienoic acid, 5-phenylpenta-2,4-dienoic acid, 2-hydroxypenta-2,4-dienoic acid, 2,4-hexadienoic acid (sorbic acid), 4,5-hexadienoic acid, 4,6-heptadienoic acid, 2,6-dimethylhepta-2,5-dienoic acid, (3E,5E)-hepta-3,5-dienoic acid, (2E,5Z)-Hepta-2,5-dienoic acid, octa-3,5-dienoic acid, (Z)-3,7-dimethyl-2,6-octadienoic acid, 5,7-nonadienoic acid, (E,Z)-2,4-decadienoic acid, 2,5-decadienoic acid, undecadienoic acid, dodecadienoic acid, tridecadienoic acid, tetradecadienoic acid, pentadecadienoic acid, hexadecadienoic acid, heptadecadienoic acid, (9Z,12E)-octadeca-9,12-dienoic acid, octadeca-10,12-dienoic acid, (10E,15Z)-9,12,13-trihydroxyoctadeca-10,15-dienoic acid, 13 (S)-hydroxyoctadeca-9Z,11E-dienoic acid, nonadecadienoic acid, henicosadienoic acid, docosadienoic acid, eicosa-11,14-dienoic acid, salts thereof, and mixtures thereof.

In one or more embodiments, the at least one organic acid is included in the composition in an amount from about 0.00001% to about 50% by weight of the cleaning composition. For example, the at least one organic acid can be at least about 0.00001% (e.g., at least about 0.00005%, at least about 0.0001%, at least about 0.0005%, at least about 0.001%, at least about 0.005%, at least about 0.01%, at least about 0.05%, at least about 0.1%, at least about 0.5%, or at least about 1%) by weight to at most about 50% (e.g., at most about 45%, at most about 40%, at most about 35%, at most about 30%, at most about 25%, at most about 20%, at most about 15%, at most about 10%, at most about 5%, or at most about 1%) by weight of the cleaning composition described herein.

In one or more embodiments, the cleaning composition described herein can include at least one first organic acid. In some embodiments, the at least one first organic acid can be selected from the group consisting of carboxylic acids (e.g., monocarboxylic acids and polycarboxylic acids (such as bicarboxylic acids and tricarboxylic acids)), sulfonic acids, phosphoric acid, acrylic acids, peracids, and phosphonic acids. In some embodiments, the at least one first organic acid can be an acid selected from the group consisting of formic acid, gluconic acid, acetic acid, malonic acid, citric acid, propionic acid, malic acid, adipic acid, succinic acid, lactic acid, oxalic acid, hydroxyethylidene diphosphonic acid, 2-phosphono-1,2,4-butane tricarboxylic acid, aminotrimethylene phosphonic acid, hexamethylenediamine tetra(methylenephosphonic acid), bis(hexamethylene) triamine phosphonic acid, peracetic acid, phenoxyacetic acid, benzoic acid, ethylenediaminetetraacetic acid (EDTA), diethylenetriaminepentaacetic acid, (DTPA), and mixtures thereof. In some embodiments, the at least one first organic acid can be a tricarboxylic acid (e.g., citric acid). In some embodiments, the at least one first organic acid does not include an amino acid or a dienoic acid.

In one or more embodiments, the at least one first organic acid can be at least about 0.00001% (e.g., at least about 0.00005%, at least about 0.0001%, at least about 0.0005%, at least about 0.001%, at least about 0.005%, at least about 0.01%, at least about 0.05%, at least about 0.1%, at least about 0.5%, or at least about 1%) by weight to at most about 50% (e.g., at most about 45%, at most about 40%, at most about 35%, at most about 30%, at most about 25%, at most about 20%, at most about 15%, at most about 10%, at most about 8%, at most about 6%, at most about 5%, at most about 4%, at most about 2%, or at most about 1%) by weight of the cleaning composition described herein.

In one or more embodiments, the cleaning composition described herein can optionally include at least one second organic acid different from the at least one first organic acid. In some embodiments, the at least one second organic acid can be a dienoic acid (i.e., an acid containing a diene). In some embodiments, the dienoic acid can have from 5 to 22 carbons (e.g., 5, 6, 7, 8, 9, 10, 11, 12, 13, 14, 15, 16, 17, 18, 19, 20, 21, or 22) carbons. In some embodiments, the dienoic acid can have from 5 to 12 (e.g., 5, 6, 7, 8, 9, 10, 11, or 12) carbons. In some embodiments, the dienoic acid can be a carboxylic acid containing a diene, such as 2,4-pentadienoic acid, 5-phenylpenta-2,4-dienoic acid, 2-hydroxypenta-2,4-dienoic acid, 2,4-hexadienoic acid (sorbic acid), 4,5-hexadienoic acid, 4,6-heptadienoic acid, 2,6-dimethylhepta-2,5-dienoic acid, (3E,5E)-hepta-3,5-dienoic acid, (2E,5Z)-hepta-2,5-dienoic acid, octa-3,5-dienoic acid, (Z)-3,7-dimethyl-2,6-octadienoic acid, 5,7-nonadienoic acid, (E,Z)-2,4-decadienoic acid, 2,5-decadienoic acid, undecadienoic acid, dodecadienoic acid, tridecadienoic acid, tetradecadienoic acid, pentadecadienoic acid, hexadecadienoic acid, heptadecadienoic acid, (9Z,12E)-octadeca-9,12-dienoic acid, octadeca-10,12-dienoic acid, (10E,15Z)-9,12,13-trihydroxyoctadeca-10,15-dienoic acid, 13 (S)-hydroxyoctadeca-9Z,11E-dienoic acid, nonadecadienoic acid, henicosadienoic acid, docosadienoic acid, eicosa-11,14-dienoic acid, or mixtures thereof.

In one or more embodiments, the at least one second organic acid can be at least about 0.0001% (e.g., at least about 0.0005%, at least about 0.001%, at least about 0.005%, at least about 0.01%, at least about 0.02%, at least about 0.04%, or at least about 0.05%) by weight to at most about 0.5% (e.g., at most about 0.4%, at most about 0.3%, at most about 0.2%, at most about 0.1%, at most about 0.08%, at most about 0.06%, at most about 0.05%, at most about 0.04%, at most about 0.03%, at most about 0.02%, at most about 0.01%, or at most about 0.005%) by weight of the cleaning composition described herein.

Without wishing to be bound by theory, it is believed that including the second organic acid (e.g., a dienoic acid) in the above amount range can improve corrosion inhibition of certain metals and metal containing films (e.g., W, Cu, TaN, or TiN) on the substrate during a post-CMP cleaning process. Further, electrochemical studies on some cleaning compositions containing a dienoic acid (e.g., sorbic acid) showed better metal (e.g., W) corrosion protection than P-CMP compositions without a dienoic acid.

In one or more embodiments, the cleaning composition described herein can optionally include at least one (e.g., two or three) corrosion inhibitor that is an amino acid different from the at least one first and second organic acids. In general, the at least one corrosion inhibitor can be a naturally occurring amino acid or a non-naturally occurring amino acid. In some embodiments, the at least one corrosion inhibitor can be selected from the group consisting of amino carboxylic acid (e.g., amino acetic acid), glycine, bicine, tricine, alanine, histidine, valine, phenylalanine, proline, glutamine, aspartic acid, glutamic acid, arginine, lysine, tyrosine, and mixtures thereof.

In one or more embodiments, the at least one corrosion inhibitor can be at least about 0.001% (e.g., at least about 0.005%, at least about 0.01%, at least about 0.05%, at least about 0.1%, at least about 0.5%, or at least about 1%) by weight to at most about 20% (e.g., at most about 18%, at most about 16%, at most about 15%, at most about 14%, at most about 12%, at most about 10%, at most about 8%, at most about 6%, at most about 5%, at most about 4%, at most about 2%, at most about 1%, or at most about 0.5%) by weight of the cleaning composition described herein.

In one or more embodiments, the cleaning composition described herein includes two organic acids, such as (1) citric acid and histidine or (2) citric acid and glycine. In some embodiments, the cleaning composition includes three organic acids, such as (1) citric acid, histidine, and sorbic acid or (2) citric acid, histidine, and glycine. In some embodiments, the cleaning composition includes four organic acids (e.g., citric acid, histidine, sorbic acid and glycine).

In one or more embodiments, the cleaning composition can include at least two or three organic acids (e.g., a carboxylic acid, an amino acid, and/or a dienoic acid). In some embodiments, the first organic acid (e.g., a carboxylic acid) is in an amount of from about 0.0005% to about 10% by weight of the cleaning composition described herein. In some embodiments, the second organic acid (e.g., a dienoic acid) is in an amount of from about 0.0005% to about 0.5% by weight of the cleaning composition described herein. In yet some other embodiments, the third organic acid (e.g., an amino acid) is in an amount of from about 0.005 to about 5% by weight of the cleaning composition described herein.

In one or more embodiments, the cleaning composition described herein can optionally include at least one (e.g., two or three) anionic polymer. In one or more embodiments, the at least one anionic polymer can include one or more anionic groups, such as carboxylate, sulfate, and phosphate groups. In one or more embodiments, the at least one anionic polymer is formed from one or more monomers selected from the group consisting of (meth)acrylic acid, maleic acid, acrylic acid, malic acid, methacrylic acid, vinyl phosphonic acid, vinyl phosphoric acid, vinyl sulfonic acid, allyl sulfonic acid, styrene sulfonic acid, acrylamidopropyl sulfonic acid, and sodium phosphinite. In more specific embodiments, the at least one anionic polymer can be selected from the group consisting of poly (4-styrenylsulfonic) acid (PSSA), polyacrylic acid (PAA), poly (vinylphosphonic acid) (PVPA), poly (2-acrylamido-2-methyl-1-propanesulfonic acid), poly (N-vinylacetamide) (PNVA), anionic poly (methyl methacrylate) (PMMA), anionic polyacrylamide (PAM), polyaspartic acid (PASA), anionic poly (ethylene succinate) (PES), anionic polybutylene succinate (PBS), 2-propenoic acid copolymer with 2-methyl-2-((1-oxo-2-propenyl) amino)-1-propanesulfonic acid monosodium salt and sodium phosphinite, 2-propenoic acid copolymer with 2-methyl-2-((1-oxo-2-propenyl) amino)-1-propanesulfonic acid monosodium salt and sodium hydrogen sulfite sodium salt, 2-acrylamido-2-methyl-1-propanesulfonic acid-acrylic acid copolymer, poly (4-styrenesulfonic acid-co-acrylic acid-co-vinylphosphonic acid) terpolymer, and mixtures thereof. Without wishing to be bound by theory, it is believed that the anionic polymer can solubilize hydrophobic polishing materials and/or defects on a substrate surface and facilitate their removal during a post-CMP cleaning process.

In one or more embodiments, the at least one anionic polymer can have a weight average molecular weight ranging from at least about 250 g/mol (e.g., at least about 500 g/mol, at least about 1000 g/mol, at least about 2,000 g/mol, at least about 5,000 g/mol, at least about 10,000 g/mol, at least about 50,000 g/mol, at least about 100,000 g/mol, at least about 200,000 g/mol, or at least about 250,000 g/mol) to at most about 500,000 g/mol (e.g., at most about 400,000 g/mol, at most about 300,000 g/mol, at most about 200,000 g/mol, at most about 100,000 g/mol, or at most about 50,000 g/mol, or at most about 10,000 g/mol). In some embodiments, the at least one anionic polymer can have a weight average molecular weight ranging from at least about 1,000 g/mol to at most about 10,000 g/mol. In some embodiments, the at least one anionic polymer can have a weight average molecular weight ranging from at least about 2,000 g/mol to at most about 6,000 g/mol. In yet some embodiments, the at least one anionic polymer can have a weight average molecular weight of about 5,000 g/mol.

In some embodiments, the cleaning composition described herein includes one anionic polymer such as poly (vinylphosphonic acid), 2-acrylamido-2-methyl-1-propanesulfonic acid-acrylic acid copolymer, or poly (4-styrenesulfonic acid-co-acrylic acid-co-vinylphosphonic acid) terpolymer. In some embodiments, the cleaning composition described herein includes two anionic polymers, such as (1) poly (4-styrenylsulfonic) acid and polyacrylic acid or (2) 2-acrylamido-2-methyl-1-propanesulfonic acid-acrylic acid copolymer and poly (acrylic) acid.

In one or more embodiments, the at least one anionic polymer is included in the composition in an amount from about 0.00001% to about 50% by weight of the cleaning composition. For example, the at least one anionic polymer can be at least about 0.00001% (e.g., at least about 0.00005%, at least about 0.0001%, at least about 0.0005%, at least about 0.001%, at least about 0.005%, at least about 0.01%, at least about 0.05%, at least about 0.1%, at least about 0.5%, or at least about 1%) by weight to at most about 50% (e.g., at most about 45%, at most about 40%, at most about 35%, at most about 30%, at most about 25%, at most about 20%, at most about 15%, at most about 10%, at most about 5%, or at most about 1%) by weight of the cleaning composition described herein.

In some embodiments, the cleaning composition can include at least two or three anionic polymers. In some embodiments, the first anionic polymer is in an amount of from about 0.0005% to about 50% by weight of the cleaning composition described herein. In some embodiments, the second anionic polymer is in an amount of from about 0.0005% to about 30% by weight of the cleaning composition described herein. In yet some other embodiments, the third anionic polymer is in an amount of from about 0.0005% to about 10% by weight of the cleaning composition described herein.

In one or more embodiments, the cleaning composition described herein can include at least one (e.g., two or three) organosilane compound. In one or more embodiments, the at least one organosilane compound includes at least one acidic group or a salt thereof. In one or more embodiments, the organosilane compound can be a tetraalkyl orthosilicate (e.g., a non-limiting example of an alkoxysilane). In one or more embodiments, the acidic groups on the organosilane compound are chemically distinct. In one or more embodiments, the organosilane compound includes a nitrogen-containing group (e.g., an amino group, an ammonium group, an amide group, a diamide group, an imide group, or an imidazolyl group), an oxygen-containing group (e.g., a carboxylic acid group, a carboxylate group, an oxiranyl group, an ethyleneoxy group, a polyethyleneoxy group, an ester group, an acid anhydride group, an amide group, a diamide group, an imide group, or an alkoxy group), a sulfur-containing group (e.g., a sulfonate or sulfonic acid group), a phosphorous-containing group (e.g., a phosphonate group, a phosphonic acid group, or a phosphinic acid group), or a combination of any of these. In one or more embodiments, the organosilane compound includes a phosphonic acid or a sulfonic acid group. In some non-limiting embodiments, the at least one organosilane compound includes (1) at least one acidic group, an ester thereof, or a salt thereof (e.g., any described herein) and (2) at least one alkoxy group (e.g., —OR, in which R is linear or branched alkyl that may be substituted or unsubstituted and that may be cyclic or acyclic), alkyl group (e.g., —R, in which R is linear or branched alkyl that may be substituted or unsubstituted and that may be cyclic or acyclic), hydroxyl group (e.g., —OH or a salt thereof), hydrogen (e.g., —H), halo group (e.g., —X, in which X is fluoro, chloro, bromo, or iodo), or a combination of any of these. In some non-limiting embodiments, the at least one organosilane includes (1) at least one alkyl group (e.g., —R, in which R is linear or branched alkyl that may be substituted or unsubstituted and that may be cyclic or acyclic) and (2) further groups selected from the group consisting of an alkoxy group (e.g., —OR, in which R is linear or branched alkyl that may be substituted or unsubstituted and that may be cyclic or acyclic), alkyl group (e.g., —R, in which R is linear or branched alkyl that may be substituted or unsubstituted and that may be cyclic or acyclic), hydroxyl group (e.g., —OH or a salt thereof), hydrogen (e.g., —H), halo group (e.g., —X, in which X is fluoro, chloro, bromo, or iodo), or a combination of any of these. In some non-limiting embodiments, the at least one organosilane includes (1) at least one amino group (e.g., —NR^{N1}R^{N2} or —NR^{N1}—, in which each of R^{N1} and R^{N2} is, independently, H or a linear or branched alkyl that may be substituted or unsubstituted and that may be cyclic or acyclic) and (2) further groups selected from the group consisting of an alkoxy group (e.g., —OR, in which R is linear or branched alkyl that may be substituted or unsubstituted and that may be cyclic or acyclic), alkyl group (e.g., —R, in which R is linear or branched alkyl that may be substituted or unsubstituted and that may be cyclic or acyclic), hydroxyl group (e.g., —OH or a salt thereof), hydrogen (e.g., —H), halo group (e.g., —X, in which X is fluoro, chloro, bromo, or iodo), or a combination of any of these. In one or more embodiments, the at least one organosilane compound is selected from the group consisting of tetramethyl orthosilicate (TMOS), tetraethyl orthosilicate (TEOS), potassium methylsiliconate, (3-glycidyloxypropyl) trimethoxy-silane, triethoxysilylpropoxy (polyethyleneoxy) dodecanoate, (3-triethoxysilyl) propylsuccinic anhydride, N-(2-aminoethyl)-3-aminopropyl-trimethoxysilane, ureidopropyltriethoxysilane, trimethylmethoxysilane, N-trimethoxysilylpropyl-N,N,N-trimethylammonium chloride, dimethyldimethoxysilane, vinyltrimethoxysilane, N-trimethoxysilylpropyl-N,N,N-trimethylammonium halide, 3-aminopropylmethyl diethoxysilane, N-(3-triethoxysilylpropyl)-4,5-dihydroimidazole, N-(6-aminohexyl) aminomethyl triethoxysilane, N-(2-aminoethyl)-3-aminoisobutylmethyl dimethoxysilane, N-(2-aminoethyl)-3-aminopropylmethyl dimethoxysilane, (N,N-diethylaminomethyl)triethoxysilane, N-methylaminopropyl trimethoxysilane, 3-(trihydroxysilyl) propyl methylphosphonate, 3-(trihydroxysilyl)-1-propanesulfonic acid, carboxyethylsilanetriol, (2-diethylphosphatoethyl)triethoxysilane, aminoethylaminopropylsilsesquioxane, [3-(trihydroxysilyl) propyl] (methyl)phosphate, (3-aminopropyl)methyldimethoxysilane, (3-aminopropyl)dimethylmethoxysilane, (3-aminopropyl)triethoxysilane, (3-aminopropyl) trimethoxysilane, N-(2-aminoethyl)-3-aminopropyltriethoxysilane, [3-(diethylamino) propyl] trimethoxysilane, 3-(2-aminoethylamino) propylmethyldimethoxysilane, 3-(trimethylsilyl)-1-propanesulfonic acid, 3-{[dimethyl (3-trimethoxysilyl) propyl] ammonio} propane-1-sulfonate, salts thereof, or combinations thereof.

In one or more embodiments, the at least one organosilane compound is in an amount from about 0.0001% to 20% by weight of the cleaning composition. For example, the at least one organosilane compound can be at least about 0.0001% (e.g., at least about 0.0005%, at least about 0.001%, at least about 0.005%, at least about 0.01%, at least about 0.05%, at least about 0.1%, at least about 0.5%, at least about 1%, at least about 2.5%, or at least about 3%) by weight to at most about 20% (e.g., at most about 15%, at most about 12.5%, at most about 10%, at most about 7.5%, at most about 5%, at most about 2.5%, or at most about 1%) by weight of the cleaning composition described herein.

In one or more embodiments, the cleaning composition can optionally include at least one (e.g., two or three) pH adjuster selected from the group consisting of lithium hydroxide, potassium hydroxide, sodium hydroxide, cesium hydroxide, ammonium hydroxide, triethanolamine, diethanolamine, monoethanolamine, methylethanolamine, methyldiethanolamine, tetrabutylammonium hydroxide, tetrapropylammonium hydroxide, tetraethylammonium hydroxide, tetramethylammonium hydroxide, ethyltrimethylammonium hydroxide, diethyldimethylammonium hydroxide, dimethyldipropylammonium hydroxide, benzyltrimethylammonium hydroxide, tris (2-hydroxyethyl)methylammonium hydroxide, tris (hydroxymethyl)aminoethane, choline hydroxide, and mixtures thereof.

In one or more embodiments, the at least one pH adjuster is in an amount from about 0.001% (e.g., at least about 0.005%, at least about 0.01%, at least about 0.05%, at least about 0.1%, at least about 0.5%, at least about 1%, at least about 5%) by weight to about 15% (e.g., at most about 12.5%, at most about 10%, at most about 7.5%, at most about 5%, at most about 2.5%, at most about 1%, or at most about 0.5%) by weight of the cleaning composition described herein.

In some embodiments, the pH value of the cleaning composition can range from at most about 14 (e.g., at most 13.5, at most about 13, at most about 12.5, at most about 12, at most about 11.5, at most about 11, at most about 10.5, at most about 10, at most about 9.5, at most about 9, at most about 8.5, at most about 8, at most about 7.5, at most about 7, at most about 6.5, at most about 6, at most about 5.5, at most about 5, at most about 4.5, at most about 4, at most about 3.5, at most about 3, at most about 2.5, at most about 2, or at most about 1.5) to at least about 1 (e.g., at least about 1.5, at least about 2, at least about 2.5, at least about 3, at least about 3.5, at least about 4, at least about 4.5, or at least about 5). In one or more embodiments, the pH value of the cleaning composition can be acidic. In one or more embodiments, the pH value of the cleaning composition can be basic. Without wishing to be bound by theory, it is believed that, when the cleaning composition described herein has an acidic pH, it can provide enough protons to solubilize the organic residues generated from CMP polishing of the substrates and can provide enough cleaning action to solubilize the inert metal (e.g., W, Cu) containing polishing byproducts. Without wishing to be bound by theory, it is believed that, when the cleaning composition described herein has an alkaline pH, it may provide superior wetting of some substrate surfaces when compared with an acidic pH.

Without wishing to be bound by theory, it is believed that the cleaning composition described herein can include a much smaller concentration/amount of a single chemical material or overall chemical materials than a conventional cleaner currently used in the semiconductor industry (e.g., CLEAN-100), and still achieve better performance (e.g., better cleaning efficacy and/or lower corrosion of exposed materials on a substrate). For example, the cleaning composition described herein can include a chemical material or a total amount of chemical materials that is only about 5-20% (e.g., about 5-15%) by weight of the same chemical material (e.g., an organic acid or an anionic polymer) or a total amount of chemical materials in a conventional cleaner (e.g., CLEAN-100). As a result, it is believed that the cleaning composition described herein is more cost effective and environmentally friendly and offers a much better overall cost of ownership at point of use (as it is highly dilute-able (e.g., up to 200×)) when compared to a conventional cleaner (e.g., CLEAN-100).

In one or more embodiments, the cleaning composition described herein can be substantially free of one or more of certain ingredients, such as organic solvents, pH adjusting agents, quaternary ammonium compounds (e.g., salts such as tetraalkylammonium salts and hydroxides such as tetraalkylammonium hydroxides), alkali bases (such as alkali hydroxides), fluorine-containing compounds (e.g., fluoride compounds or fluorinated compounds (such as fluorinated polymers/surfactants)), organosilanes (e.g., those not specifically mentioned herein), silicon-containing compounds such as silanes (e.g., alkoxysilanes, including TEOS and TMOS, in which an alkoxysilane can include a compound that lacks at least one acidic group, an ester thereof, or a salt thereof (e.g., any described herein) or in which an alkoxysilane can include a compound that includes (1) at least one alkyl group (e.g., —R, in which R is linear or branched alkyl that may be substituted or unsubstituted and that may be cyclic or acyclic) and (2) further groups selected from the group consisting of an alkoxy group (e.g., —OR, in which R is linear or branched alkyl that may be substituted or unsubstituted and that may be cyclic or acyclic), alkyl group (e.g., —R, in which R is linear or branched alkyl that may be substituted or unsubstituted and that may be cyclic or acyclic), hydroxyl group (e.g., —OH or a salt thereof), hydrogen (e.g., —H), halo group (e.g., —X, in which X is fluoro, chloro, bromo, or iodo), or a combination of any of these; and aminosilanes, including aminopropyltriethoxysilane, in which an aminosilane can include a compound that lacks at least one acidic group, an ester thereof, or a salt thereof (e.g., any described herein) or in which an aminosilane can include a compound that includes (1) at least one amino group (e.g., —NR^{N1}R^{N2} or —NR^{N1}—, in which each of R^{N1} and R^{N2} is, independently, H or a linear or branched alkyl that may be substituted or unsubstituted and that may be cyclic or acyclic) and (2) further groups selected from the group consisting of an alkoxy group (e.g., —OR, in which R is linear or branched alkyl that may be substituted or unsubstituted and that may be cyclic or acyclic), alkyl group (e.g., —R, in which R is linear or branched alkyl that may be substituted or unsubstituted and that may be cyclic or acyclic), hydroxyl group (e.g., —OH or a salt thereof), hydrogen (e.g., —H), halo group (e.g., —X, in which X is fluoro, chloro, bromo, or iodo), or a combination of any of these), nitrogen-containing compounds (e.g., amino acids, amines, imines (e.g., amidines such as 1,8-diazabicyclo [5.4.0]-7-undecene (DBU) and 1,5-diazabicyclo[4.3.0] non-5-ene (DBN)), amides, or imides), polyols, salts (e.g., halide salts or metal salts), polymers (e.g., cationic, non-ionic, anionic, or water soluble polymers), inorganic acids (e.g., hydrochloric acid, sulfuric acid, phosphoric acid, or nitric acid), surfactants (e.g., cationic surfactants, anionic surfactants, non-polymeric surfactants, or non-ionic surfactants), zwitterionic compounds, plasticizers, oxidizing agents (e.g., H₂O₂ and/or periodic acid), corrosion inhibitors (e.g., azole or non-azole corrosion inhibitors), electrolytes (e.g., polyelectrolytes), dienoic acids (e.g., sorbic acid), and/or abrasives (e.g., polymeric abrasives, silica abrasives, ceria abrasives, non-ionic abrasives, surface modified abrasives, negatively/positively charged abrasives, or ceramic abrasive composites). The halide salts that can be excluded from the cleaning compositions include alkali metal halides (e.g., sodium halides or potassium halides) or ammonium halides (e.g., ammonium chloride), and can be fluorides, chlorides, bromides, or iodides. As used herein, an ingredient that is “substantially free” from a cleaning composition refers to an ingredient that is not intentionally added into the cleaning composition. In some embodiments, the cleaning composition described herein can have at most about 1000 ppm (e.g., at most about 500 ppm, at most about 250 ppm, at most about 100 ppm, at most about 50 ppm, at most about 10 ppm, or at most about 1 ppm) of one or more of the above ingredients that are substantially free from the cleaning composition. In some embodiments, the cleaning composition described herein can be completely free of one or more of the above ingredients.

In one or more embodiments, the cleaning composition described herein can include a biocide. Exemplary biocides include, but are not limited to, isothiazolinones (such as benzisothiazolinone, methylisothiazolinone, and methylchloroisothiazolinone), 2-bromo-2-nitropropane-1,3-diol, hydrogen peroxide, and combinations thereof. In some embodiments, the biocide can be in an amount of from at most about 1000 ppm (e.g., at most about 500 ppm, at most about 250 ppm, at most about 100 ppm, at most about 50 ppm, or at most about 10 ppm) to at least about 1 ppm of the cleaning composition described herein.

As applied to post-CMP cleaning operations, the cleaning compositions described herein can be usefully employed to remove contaminants present on a substrate surface after a CMP processing step. In one or more embodiments, the contaminants causing defectivity can be at least one selected from the group consisting of abrasives, particles, organic residues, polishing byproducts, slurry byproducts, slurry induced organic residues, inorganic polished substrate residues, pad debris, and polyurethane residue, etc. In one or more embodiments, the cleaning compositions of the present disclosure can be employed to remove organic residues constituted by organic particles which are insoluble in water and thus remain on the substrate surface post the CMP polishing step. In other embodiments, the cleaning compositions of the present disclosure can be employed to remove abrasive residues/particles and/or polishing byproducts, and reduce scratches that cause defectivity on the substrate surface post the CMP polishing step.

Without wishing to be bound by theory, it is believed that the organic particles are generated from polishing composition components, which deposit on a substrate surface after polishing, and are insoluble and thus remain as contaminants on the substrate surface. The presence of these contaminants causes defect counts on the substrate surface. These defect counts, when analyzed on a defect measuring tool (such as the AIT-XUV tool from KLA Company) contribute to the total defect counts (TDC) that is a sum of all the individual defect counts. In one or more embodiments, the cleaning compositions described herein remove from at least about 30% (e.g., at least about 50%, at least about 75%, at least about 80%, at least about 90%, at least about 95%, at least about 98%, at least about 99%, at least about 99.5%, or at least about 99.9%) to at most about 100% of the total defect counts (TDC) remaining on a substrate surface after the polishing/CMP process. The TDC removal from the substrate surface by the post-CMP cleaning composition is called Cleaning Efficacy of the cleaning composition and is expressed as a percentage. The higher the percentage, the better the cleaning efficacy and the more potent/powerful/effective is the cleaning composition.

Without wishing to be bound by theory, it is believed that there is a surprising and unexpected synergism with the components of the cleaning compositions described herein. For example, the organic acids can reduce scratches and solubilize metal oxide and silica containing residues (e.g., abrasive residues on a wafer) that can cause scratching, the amino acids can serve as corrosion inhibitors for metals (e.g., tungsten), and the anionic polymer is an excellent solubilizer for hydrophobic organic residues left on a substrate surface after a CMP process. Further, it is believed that the combination of a tricarboxylic organic acid (e.g., citric acid) and a dienoic acid (e.g., sorbic acid), optionally along with an amino acid (e.g., histidine or glycine) and an anionic polymer, shows significant reduction in metal galvanic corrosion, which is key to improving the yield of substrates cleaned after a CMP process.

In some embodiments, this disclosure features a method of cleaning a substrate (e.g., a wafer). The method can include contacting the substrate with the cleaning composition described herein. In post-CMP cleaning applications, the cleaning composition can be applied in any suitable manner to the substrate to be cleaned. For example, the cleaning composition can be used with a large variety of conventional cleaning tools and techniques (e.g., brush scrubbing, spin rinse dry, etc.). In one or more embodiments, after the CMP polishing step, the cleaning composition described herein can be employed in a Megasonic cleaner module or in Brush Box 1 or Brush Box 2 of Applied Materials Reflexion 300 mm CMP polishing tool. The Brush Box has brushes for scrubbing action whereas the cleaning composition provides the chemical action to remove defects. The cleaning composition can be applied on a substrate surface in the brush box or the megasonic for a time ranging from about 5 sec to about 10 minutes (e.g., from about 15 sec to 5 minutes) at a temperature in the range of 20° C. to 60° C.

In addition to the brush boxes and/or megasonic cleaner, the cleaning composition described herein can be used as an abrasive-free buffing chemistry for on-platen buffing of substrates on a CMP polisher to remove defects by buffing the substrate on a soft pad in the presence of the cleaning composition on the polishing pad. In more specific embodiments, the cleaning composition can be used in the buffing station to buff on a soft poromeric pad in the buffing station modules of the 4-platen Applied Materials Reflexion Prime 300 mm CMP polishing tool.

In some embodiments, the substrate to be cleaned can include at least one material selected from the group consisting of low-k dielectrics (e.g., porous silicon oxide with k<3.5), ultralow-k dielectrics (e.g., ultra-porous silicon oxide with k<2.5), tungsten, titanium nitride, tantalum nitride, silicon carbide, silicon oxide (e.g., TEOS), silicon nitride, copper, cobalt, molybdenum, ruthenium, Black Diamond (which can include silicon oxycarbide (e.g., SiOC, SiOC(H), or carbon doped silica)), and polysilicon (p-Si) on a substrate surface that can be exposed to the cleaning composition during a cleaning process.

In some embodiments, the method that uses a cleaning composition described herein can further include producing a semiconductor device from the substrate treated by the cleaning composition through one or more steps. For example, photolithography, ion implantation, dry/wet etching, plasma etching, deposition (e.g., PVD, CVD, ALD, ECD), wafer mounting, die cutting, packaging, and testing can be used to produce a semiconductor device from the substrate treated by the cleaning composition described herein.

Although only a few example embodiments have been described in detail below, those skilled in the art will readily appreciate that many modifications are possible in the ensuing example embodiments without materially departing from this invention. Accordingly, all such modifications are intended to be included within the scope of this disclosure as defined in the claims.

### EXAMPLES

Examples are provided to further illustrate the capabilities of the post-CMP cleaning compositions and methods of the present disclosure. The provided examples are not intended and should not be construed to limit the scope of the present disclosure. Any percentages listed are by weight (wt %) unless otherwise specified. The examples shown herein are representative and cannot encompass the complete broad scope of this invention disclosure.

### Example 1: Demonstration of Defectivity Reduction and Post-CMP Cleaning Efficacy of Inventive Post-CMP Cleaning Compositions

In this example, blanket wafers having films of TEOS, polysilicon, copper, silicon nitride, or cobalt were first polished via CMP using polishing compositions for either copper polishing or barrier film polishing. After the polishing, the wafers were then subjected to a P-CMP clean operation using a comparative post-CMP cleaning composition. The total defect counts (TDC) on the wafer at this stage were then measured to obtain an initial baseline value. The polished and cleaned wafers were then subjected to a second polishing via CMP using polishing compositions for either copper polishing or barrier film polishing. The twice polished wafers were then subjected to a P-CMP clean operation using inventive cleaning compositions according to the present disclosure. The general formulation of the inventive cleaning compositions according to the present disclosure that were tested in this Example is shown below in Table 1. The comparative post-CMP cleaning composition utilized the same components in relatively the same amounts as shown in Table 1 below, except it did not include any organosilane compound.

TABLE 1

| | % By Weight of |
|---|---|
| Component | Composition |
| pH adjuster (basic) | 0.01-0.5 |
| Corrosion Inhibitor (amino acid) | 0.001 to 0.01 |
| First Organic Acid | 0.01% to 0.05% |
| Second Organic Acid (dienoic acid) | 0.0001 to 0.001 |
| Anionic Polymer (sulfonic acid | 0.01 to 0.1 |
| containing copolymer) | |
| Organosilane 1 (phosphonic acid | 0.001-0.1 |
| containing silane) | (if used) |
| Organosilane 2 (sulfonic acid | 0.001-0.1 |
| containing silane) | (if used) |
| Organosilane 3 (alkoxysilane) | 0.001-0.1 |
| | (if used) |
| Organosilane 4 (aminosilane) | 0.001-0.1 |
| | (if used) |
| Solvent (DI Water) | Remainder |
| pH | 4-6.5 |

The total defect counts on the wafer at this stage, referred to as the “post” value, were compared with the initial baseline value to arrive at a Cleaning Efficiency value by using the formula: Cleaning Efficiency=[(Baseline TDC-Post TDC)/Baseline TDC)]. The results are compiled in Table 2 below.

TABLE 2

| | | | Cleaning | Cleaning | Cleaning | Cleaning |
|---|---|---|---|---|---|---|
| | | | Efficiency with | Efficiency with | Efficiency with | Efficiency with |
| | | | Composition 1 | Composition 2 | Composition 3 | Composition 4 |
| Test | CMP | Blanket | (including | (including | (including | (including |
| Condition | Composition | Film | Organosilane 1) | Organosilane 2) | Organosilane 3) | Organosilane 4) |
| 1 | Copper | TEOS | 14.5% | 1.5% | N/A | N/A |
| 2 | Copper | Polysilicon | 21% | 98% | 93% | 77% |
| 3 | Copper | Copper | −119% | 55% | −135% | −41% |
| 4 | Barrier | Polysilicon | 10% | −61% | 14% | −7% |
| 5 | Barrier | Silicon | 45% | 18% | 63% | 56% |
| | | Nitride | | | | |
| 6 | Barrier | Copper | 16% | 31% | 5% | 72% |
| 7 | Barrier | Cobalt | 96% | 71% | N/A | N/A |
| 8 | Barrier | TEOS | 36.5% | 57% | N/A | N/A |

The results in Table 2 show that both cleaning compositions of the present disclosure significantly improved the cleaning of blanket wafers of a variety of films when compared against the comparative cleaning composition. This cleaning efficiency improvement can result in improved device yield and lower waste when manufacturing semiconductor devices.

While this disclosure has been described with respect to the examples set forth herein, it is understood that other modifications and variations are possible without departing from the spirit and scope of the disclosure as defined in the appended claims.

What is claimed is:

1. A cleaning composition comprising:
at least one first organic acid;
at least one organosilane compound; and
water;
wherein the cleaning composition is substantially free of an abrasive.

2. The composition of claim 1, wherein the at least one first organic acid comprises a monocarboxylic acid or a polycarboxylic acid.

3. The composition of claim 1, wherein the at least one first organic acid is selected from the group consisting of formic acid, acetic acid, malonic acid, citric acid, propionic acid, malic acid, adipic acid, succinic acid, aspartic acid, ascorbic acid, lactic acid, oxalic acid, hydroxyethylidene diphosphonic acid, 2-phosphono-1,2,4-butane tricarboxylic acid, aminotrimethylene phosphonic acid, hexamethylenediamine tetra(methylenephosphonic acid), bis(hexamethylene)triamine phosphonic acid, peracetic acid, phenoxyacetic acid, benzoic acid, ethylenediaminetetraacetic acid, diethylenetriaminepentaacetic acid, and mixtures thereof.

4. The composition of claim 1, wherein the at least one first organic acid is selected from the group consisting of acetic acid, malonic acid, citric acid, propionic acid, malic acid, succinic acid, ascorbic acid, lactic acid, oxalic acid, and mixtures thereof.

5. The composition of claim 1, wherein the at least one first organic acid is in an amount of from about 0.00001% to about 50% by weight of the composition.

6. The composition of claim 1, wherein the at least one organosilane compound comprises a nitrogen-containing group, an oxygen-containing group, a sulfur-containing group, or a phosphorous-containing group.

7. The composition of claim 1, wherein the at least one organosilane compound is selected from the group consisting of tetramethyl orthosilicate (TMOS), tetraethyl orthosilicate (TEOS), potassium methylsiliconate, (3-glycidyloxypropyl) trimethoxy-silane, triethoxysilylpropoxy (polyethyleneoxy) dodecanoate, (3-triethoxysilyl) propylsuccinic anhydride, N-(2-aminoethyl)-3-aminopropyl-trimethoxysilane, ureidopropyltriethoxysilane, trimethylmethoxysilane, N-trimethoxysilylpropyl-N, N,N-trimethylammonium chloride, dimethyldimethoxysilane, vinyltrimethoxysilane, N-trimethoxysilylpropyl-N,N,N-trimethylammonium halide, 3-aminopropylmethyl diethoxysilane, N-(3-triethoxysilylpropyl)-4,5-dihydroimidazole, N-(6-aminohexyl)aminomethyl triethoxysilane, N-(2-aminoethyl)-3-aminoisobutylmethyl dimethoxysilane, N-(2-aminoethyl)-3-aminopropylmethyl dimethoxysilane, (N,N-diethylaminomethyl)triethoxysilane, N-methylaminopropyl trimethoxysilane, 3-(trihydroxysilyl) propyl methylphosphonate, 3-(trihydroxysilyl)-1-propanesulfonic acid, carboxyethylsilanetriol, (2-diethylphosphatoethyl)triethoxysilane, aminoethylaminopropylsilsesquioxane, [3-(trihydroxysilyl) propyl] (methyl)phosphate, (3-aminopropyl)methyldimethoxysilane, (3-aminopropyl)dimethylmethoxysilane, (3-aminopropyl)triethoxysilane, (3-aminopropyl) trimethoxysilane, N-(2-aminoethyl)-3-aminopropyltriethoxysilane, [3-(diethylamino) propyl] trimethoxysilane, 3-(2-aminoethylamino) propylmethyldimethoxysilane, 3-(trimethylsilyl)-1-propanesulfonic acid, 3-{[dimethyl (3-trimethoxysilyl) propyl] ammonio} propane-1-sulfonate, and combinations thereof.

8. The composition of claim 1, wherein the at least one organosilane compound is in an amount of from about 0.0001% to 20% by weight of the composition.

9. The composition of claim 1, further comprising:
at least one second organic acid different from the at least one first organic acid, the at least one second organic acid comprising a dienoic acid.

10. The composition of claim 9, where the at least one second organic acid comprises a dienoic acid having from 5 to 22 carbons.

11. The composition of claim 10, wherein the at least one second organic acid comprises 2,4-pentadienoic acid, 5-phenylpenta-2,4-dienoic acid, 2-hydroxypenta-2,4-dienoic acid, 2,4-hexadienoic acid, 4,5-hexadienoic acid, 4,6-heptadienoic acid, 2,6-dimethylhepta-2,5-dienoic acid, (3E,5E)-hepta-3,5-dienoic acid, (2E,5Z)-hepta-2,5-dienoic acid, octa-3,5-dienoic acid, (Z)-3,7-dimethyl-2,6-octadienoic acid, 5,7-nonadienoic acid, (E,Z)-2,4-decadienoic acid, 2,5-decadienoic acid, undecadienoic acid, dodecadienoic acid, tridecadienoic acid, tetradecadienoic acid, pentadecadienoic acid, hexadecadienoic acid, heptadecadienoic acid, (9Z,12E)-octadeca-9,12-dienoic acid, octadeca-10,12-dienoic acid, (10E,15Z)-9,12,13-trihydroxyoctadeca-10,15-dienoic acid, 13 (S)-hydroxyoctadeca-9Z,11E-dienoic acid, nonadecadienoic acid, henicosadienoic acid, docosadienoic acid, eicosa-11,14-dienoic acid, or a mixture thereof.

12. The composition of claim 9, wherein the at least one second organic acid is in an amount of from about 0.0001% to about 0.5% by weight of the composition.

13. The composition of claim 1, further comprising at least one corrosion inhibitor, wherein the at least one corrosion inhibitor is an amino acid that is chemically distinct from the at least one first and second organic acids.

14. The composition of claim 13, wherein the at least one corrosion inhibitor comprises amino carboxylic acid, glycine, bicine, tricine, alanine, histidine, valine, phenylalanine, proline, glutamine, aspartic acid, glutamic acid, arginine, lysine, tyrosine, or a mixture thereof.

15. The composition of claim 13, wherein the at least one corrosion inhibitor is in an amount of from about 0.001% to about 20% by weight of the composition.

16. The composition of claim 1, further comprising at least one anionic polymer.

17. The composition of claim 16, wherein the at least one anionic polymer is formed from one or more monomers selected from the group consisting of (meth)acrylic acid, maleic acid, acrylic acid, malic acid, methacrylic acid, vinyl phosphonic acid, vinyl phosphoric acid, vinyl sulfonic acid, allyl sulfonic acid, styrene sulfonic acid, acrylamidopropyl sulfonic acid, phosphonic acid, phosphoric acid, butadiene/maleic acid, caprolactam, etherimide, 2-ethyl-2-oxazoline, N-iso-propylacrylamide, sodium phosphinite and co-formed products thereof, and sodium, potassium, and ammonium salts thereof.

18. The composition of claim 16, wherein the at least one anionic polymer comprises poly (4-styrenylsulfonic) acid (PSSA), polyacrylic acid (PAA), poly (vinylphosphonic acid) (PVPA), poly (2-acrylamido-2-methyl-1-propanesulfonic acid), poly (N-vinylacetamide) (PNVA), anionic poly (methyl methacrylate) (PMMA), anionic polyacrylamide (PAM), polyaspartic acid (PASA), anionic poly (ethylene succinate) (PES), anionic polybutylene succinate (PBS), 2-propenoic acid copolymer with 2-methyl-2-((1-oxo-2-propenyl)amino)-1-propanesulfonic acid monosodium salt and sodium phosphinite, 2-propenoic acid copolymer with 2-methyl-2-((1-oxo-2-propenyl)amino)-1-propanesulfonic acid monosodium salt and sodium hydrogen sulfite sodium salt, 2-acrylamido-2-methyl-1-propanesulfonic acid-acrylic acid copolymer, poly (4-styrenesulfonic acid-co-acrylic acid-co-vinylphosphonic acid) terpolymer, or a mixture thereof.

19. The composition of claim 16, wherein the at least one anionic polymer comprises poly (4-styrenylsulfonic) acid (PSSA), polyacrylic acid (PAA), poly (vinylphosphonic acid) (PVPA), poly (2-acrylamido-2-methyl-1-propanesulfonic acid), poly (N-vinylacetamide) (PNVA), anionic poly (methyl methacrylate) (PMMA), anionic polyacrylamide (PAM), 2-acrylamido-2-methyl-1-propanesulfonic acid-acrylic acid copolymer, poly (4-styrenesulfonic acid-co-acrylic acid-co-vinylphosphonic acid) terpolymer, or a mixture thereof.

20. The composition of claim 16, wherein the at least one anionic polymer is in an amount of from about 0.00001% to about 50% by weight of the composition.

21. The composition of claim 1, wherein the pH of the composition is from about 1 to about 14.

22. A method for cleaning a substrate surface, comprising contacting a substrate having a surface comprising SiN, SiC, TiN, W, Ru, Mo, TEOS, Cu, TaN, Co, silicon oxycarbide, or p-Si with the cleaning composition of claim 1.

23. A method for cleaning a substrate, comprising:
contacting a substrate with the cleaning composition of claim 1.
